(19) United States
(12) Patent Application Publication
(10) Pub. No.: US 2021/0375771 A1
(43) Pub. Date: Dec. 2, 2021

(54) ELECTRONIC DEVICE

(71) Applicant: FUJITSU LIMITED, Kawasaki-shi (JP)

(72) Inventors: KENJI FUKUZONO, Kawasaki (JP); MANABU WATANABE, Yokohama (JP); Yuki Hoshino, Yokohama (JP); Hiroshi Onuki, Yokohama (JP)

(73) Assignee: FUJITSU LIMITED, Kawasaki-shi (JP)

(21) Appl. No.: 17/177,247

(22) Filed: Feb. 17, 2021

(30) Foreign Application Priority Data
May 26, 2020 (JP) 2020-091434

(51) Int. Cl. H01L 23/538; H01L 25/18

(52) U.S. Cl. CPC H01L 23/5386; H01L 25/18; H01L 23/5384

(57) ABSTRACT

An electronic device includes a bus bar that includes a first terminal and a second terminal and extends between the first terminal and the second terminal on a side of a first surface of a substrate; first solder configured to pass through the substrate in a thickness direction and connect a first through terminal connected to a first electronic component that is disposed on a second surface side of the substrate and the first terminal; and second solder configured to pass through the substrate in the thickness direction and connect a second through terminal connected to a second electronic component disposed on the second surface side of the substrate and the second terminal.

### CROSS-REFERENCE TO RELATED APPLICATION

This application is based upon and claims the benefit of priority of the prior Japanese Patent Application No. 2020-91434, filed on May 26, 2020, the entire contents of which are incorporated herein by reference.

### FIELD

The embodiment discussed herein is related to an electronic device.

### BACKGROUND

Traditionally, there has been a bus bar joining structure in which bus bars that are disposed at intervals on a circuit board are joined to a joined portion of the above circuit board by soldering. A joint portion that may have contact with the above joined portion is formed by being bent in an end portion of the bus bar, and a reinforcing portion that holds a bending angle between the above joint portion and a portion on the base side than the joint portion at a certain angle is integrally formed with the bent portion. Then, the above joint portion is soldered in a state where the above joint portion has surface contact with the above joined portion. For example, Japanese Laid-open Patent Publication No. 2010-080574 or the like is disclosed as related art.

### SUMMARY

According to an aspect of the embodiments, an electronic device includes a bus bar that includes a first terminal and a second terminal and extends between the first terminal and the second terminal on a side of a first surface of a substrate; first solder configured to pass through the substrate in a thickness direction and connect a first through terminal connected to a first electronic component that is disposed on a second surface side of the substrate and the first terminal; and second solder configured to pass through the substrate in the thickness direction and connect a second through terminal connected to a second electronic component disposed on the second surface side of the substrate and the second terminal.

The object and advantages of the invention will be realized and attained by means of the elements and combinations particularly pointed out in the claims,

It is to be understood that both the foregoing general description and the following detailed description are exemplary and explanatory and are not restrictive of the invention,

### BRIEF DESCRIPTION OF DRAWINGS

FIG. 1 is a cross-sectional diagram illustrating a configuration of an electronic device 1 that includes a bus bar connection structure 100 according to an embodiment;

FIG. 2 is a cross-sectional diagram illustrating a bus bar 110, solder 120A and 120B, and pads 12A and 12B;

FIG. 3 is an enlarged diagram illustrating a portion of a terminal 111 of the bus bar 110;

FIG. 4 is a diagram illustrating a bus bar 50 for comparison;

FIG. 5 is a diagram for explaining current distribution in solder 52 connected to a terminal of the bus bar 50;

FIG. 6 is a diagram illustrating current distribution of the solder 120A;

FIG. 7 is a diagram illustrating a simulation result of a current density of the solder 120A;

FIG. 8 is a diagram illustrating a simulation result of a current density of the solder 52 connected on a terminal 51 of the bus bar 50 for comparison; and

FIG. 9 is a cross-sectional diagram illustrating a bus bar 110M according to a modification of the embodiment.

### DESCRIPTION OF EMBODIMENTS

By the way, in a traditional bus bar joining structure, a thickness of the solder between the circuit board and the joint portion of the bus bar is fixed. Therefore, currents are concentrated in a portion to be shortest path, and the portion joined by solder is easily damaged by electromigration.

In view of the above, it is desirable to provide a bus bar connection structure that suppresses an increase in a current density.

Hereinafter, an embodiment to which a bus bar connection structure of the embodiment is applied will be described.

<Embodiment>

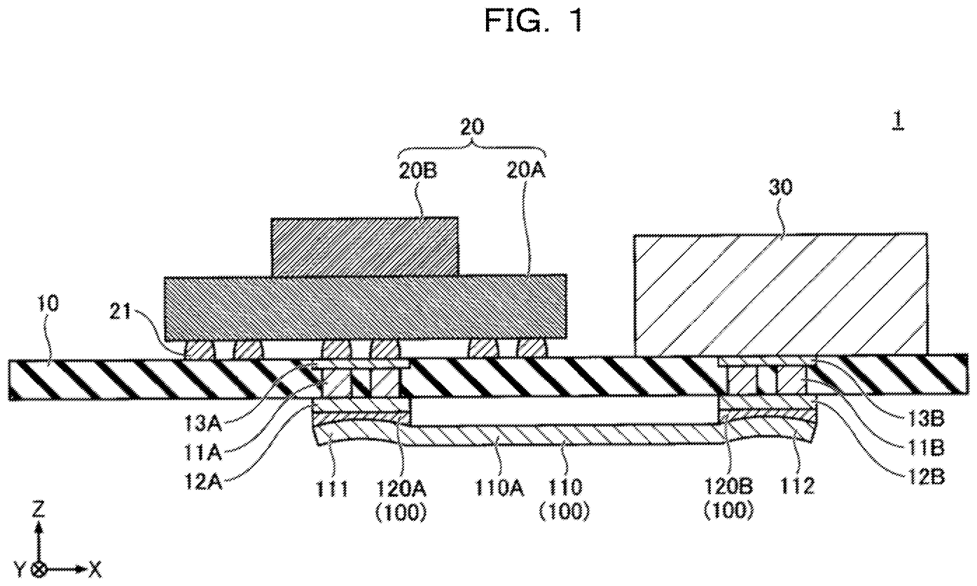

FIG. 1 is a cross-sectional diagram illustrating a configuration of an electronic device 1 that includes a bus bar connection structure 100 according to an embodiment Hereinafter, description will be made while defining an XYZ coordinate system. Furthermore, hereinafter, the plane view indicates an XY plane view. Although a−Z direction side is indicated as a lower side or below and a+Z direction is indicated as an upper side or above for convenience of the description, these do not represent a universal vertical relationship.

The electronic device 1 includes a substrate 10, a processor package 20, a Direct Current (DC)/DC converter 30, a bus bar 110, and solder 120A and 120B as main components. Of these, because the bus bar 110 and the solder 120A and 120B are included in the bus bar connection structure 100, a reference numeral 100 is written in parentheses. The processor package 20 is an example of a first electronic component and includes a package substrate 20A and a processor 20B. The DC/DC converter 30 is an example of a second electronic component. The solder 120A and the solder 120B are respectively examples of a first connection unit and a second connection unit.

The substrate 10 may be any substrate. Here, as an example, the substrate 10 is a PCI-Express standard wiring substrate. A lower surface of the substrate 10 is an example of a first surface, and an upper surface is an example of a second surface. The substrate 10 includes vias 11A and 11B and pads 12A, 12B, 13A, and 13B. The via 11A and the pads 12A and 13A are provided on the −X direction side, and the via 11B and the pads 12B and 13B are provided on the +X direction side.

The vias 11A and 116 are respectively examples of a first through terminal and a second through terminal and pass through the substrate 10 in a thickness direction (Z direction). The vias 11A and 11B are, as an example, made of copper plating, and the plurality of vias 11A and the plurality of vias 11B are provided. The pads 12A and 12B are provided on the lower surface of the substrate 10 and respectively connected to lower ends of the vias 11A and 11B. The pads 13A and 13B are provided on the upper surface of the substrate 10 and are respectively connected to upper ends of the vias 11A and 11B.

The package substrate 20A of the processor package 20 is mounted on the upper surface side of the substrate 10 and is connected to the pad 13A via a bump 21. The processor 20B is mounted on the upper surface of the package substrate 20A. The DC/DC converter 30 is mounted on the upper surface side of the substrate 10 and is connected to the pad 13B.

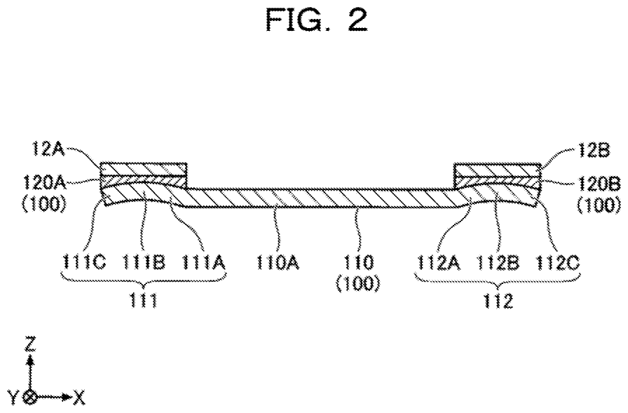

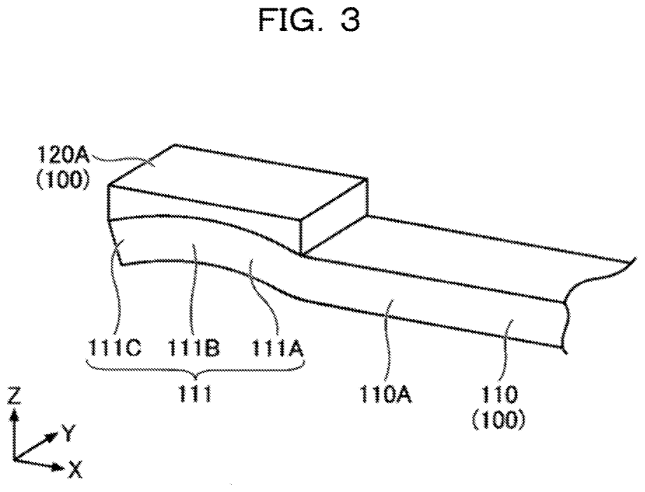

The bus bar 110 includes a base 110A and terminals 111 and 112. The bus bar 110 is made of copper, as an example, and the terminals 111 and 112 are provided at both ends of the base 110A that extends in the X direction. An extending direction of the bus bar 110 is an X direction. The terminals 111 and 112 are respectively examples of a first terminal and a second terminal. The terminals 111 and 112 are respectively connected to the pads 12A and 12B by the solder 120A and 120B. In the following, description will be made with reference to FIGS. 2 and 3 in addition to FIG. 1.

FIG. 2 is a cross-sectional diagram illustrating. the bus bar 110, the solder 120A and 120B, and the pads 12A and 12B. FIG. 3 is an enlarged diagram illustrating a portion of the terminal 111 of the bus bar 110. The terminal 111 includes an end portion 111A, a curved portion 111B, and a front end portion 111C, and the curved portion 111B is curved upward and toward the pad 12A with respect to the end portion 111A and the front end portion 111C. In the terminal 111, the end portion 111A and the front end portion 111C are positioned at both ends in the X direction, and the curved portion 111B is positioned at the central portion in the X direction. The end portion 111A is an example of a first end portion, the curved portion 111B is an example of a first approaching portion, and the front end portion 111C is an example of a side farther from the terminal 112 than the curved portion 111B.

Because the via 11A (refer to FIG. 1) is provided above the pad 12A, the fact to curve the curved portion 111B upward and toward the pad 12A with respect to the end portion 111A and the front end portion 111C is synonymous with to curve the curved portion 111B upward and toward the via 11A with respect to the end portion 111A and the front end portion 111C. Therefore, a portion of the terminal 111 from the end portion 111A to the curved portion 111B is curved toward the via 11A, and a portion from the curved portion 111B to the front end portion 111C is curved to be separated from the via 11A.

The curved portion 111B is positioned closer to the via 11A than the end portion 111A and the front end portion 111C in the vertical direction. The curved portion 111B is curved so as to draw an arc in the XZ cross-sectional view and so as to be a convex upward between the end portion 111A and the front end portion 111C. Being curved is an example of being bent. A curve means to continuously bend as a curved line.

The terminal 111 is connected to the pad 12A by the solder 120A. An upper surface of the terminal 111 having contact with the solder 120A is an example of a first contact surface. Furthermore, a lower surface of the terminal 111 is an example of a first opposite surface. Such a curved terminal 111 can be easily formed by, as an example, pressing, or the like.

The terminal 112 includes an end portion 112A, a curved portion 1126, and a front end portion 112C, and the curved portion 112B is curved upward and toward the pad 12A with respect to the end portion 112A and the front end portion 112C. In the terminal 112, the end portion 112A and the front end portion 112C are positioned at both ends in the X direction, and the curved portion 112B is positioned at the central portion in the X direction. The end portion 112A is an example of a second end portion, the curved portion 112B is an example of a second approaching portion, and the front end portion 112C is an example of a side farther from the terminal 111 than the curved portion 112B. The terminal 112 has a shape symmetrical with the terminal 111 in the X direction.

Because the via 118 (refer to FIG. 1) is provided above the pad 126, to curve the curved portion 112B upward and toward the pad 12B with respect to the end portion 112A and the front end portion 112C is synonymous with to curve the curved portion 112B upward and toward the via 116 with respect to the end portion 112A and the front end portion 112C. Therefore, a portion of the terminal 112 from the end portion 112A to the curved portion 112B is curved toward the via 116, and a portion from the curved portion 112B to the front end portion 112C is curved to be separated from the via 116.

The curved portion 112B is positioned closer to the via 11B than the end portion 112A and the front end portion 112C in the vertical direction. The curved portion 112B is curved so as to draw an arc in the XZ cross-sectional view and so as to be a convex upward between the end portion 112A and the front end portion 112C.

The terminal 112 is connected to the pad 12B by the solder 1208. An upper surface of the terminal 112 having contact with the solder 120B is an example of a second contact surface. Furthermore, a lower surface of the terminal 112 is an example of a second opposite surface. Such a curved terminal 112 can be easily formed by, as an example, pressing, or the like.

The solder 120A connects between the surface of the terminal 111 that is curved upward and a flat lower surface of the pad 12A. As an example, a solder material is applied to one of the surface of the terminal 111 that is curved upward and the flat lower surface of the pad 12A by a printing method or the like, the solder material is melted by heating the terminal 111 and the pad 12A, and the melted material is cooled in a state where the terminal 111 and the pad 12A are positioned. Accordingly, it is possible to connect the terminal 111 and the pad 12A by the solder 120A. Regarding a thickness of the solder 120A, portions above the end portion 111A and the front end portion 111C are thicker than a portion above the curved portion 111B.

The solder 120B connects between the surface of the terminal 112 that is curved upward and a flat lower surface of the pad 12B. As an example, a solder material is applied to one of the surface of the terminal 112 that is curved upward and the flat lower surface of the pad 12B by a printing method or the like, the solder material is melted by heating the terminal 112 and the pad 12B, and the melted material is cooled in a state where the terminal 112 and the pad 12B are positioned. Accordingly, it is possible to connect the terminal 112 and the pad 12B by the solder 120B. Regarding a thickness of the solder 120B, portions above the end portion 112A and the front end portion 112C are thicker than a portion above the curved portion 112B.

In this way, by respectively connecting the terminals 111 and 112 and the pads 12A and 12B by the solder 120A and 120B, the vias 11A and 11B can be connected via the bus bar 110, and it is possible to supply electronic power output by the DC/DC converter 30 to the processor package 20 via the bus bar 110.

The bus bar 110 is much thicker and has a lower resistivity than a thin wiring line formed on a general wiring substrate. Furthermore, the plurality of vias 11A and the plurality of vias 118 provided on the substrate 10 are much thicker and have a lower resistivity than a thin wiring line formed on a general wiring substrate. Therefore, it is possible to efficiently supply electronic power from the DC/DC converter 30 to the processor package 20. With a recent increase in performance and a frequency (for example, 4 GHz to 5 GHz) of processors, an amount of electronic power to be supplied to the processor is increased. However, by supplying electronic power by using the bus bar 110 and the vias 11A and 11B in this way, it is possible to reduce a power loss, a power supply noise caused by a current fluctuation, or the like. Furthermore, a configuration is considered in which the DC/DC converter 30 is directly connected to the lower side of the via 11A without using the bus bar 110. However, there is a case where a dimension in the Z direction is restricted. As an example, in a case where the processor package 20 and the DC/DC converter 30 are horizontally arranged due to such a restriction, to use the bus bar 110 is very effective.

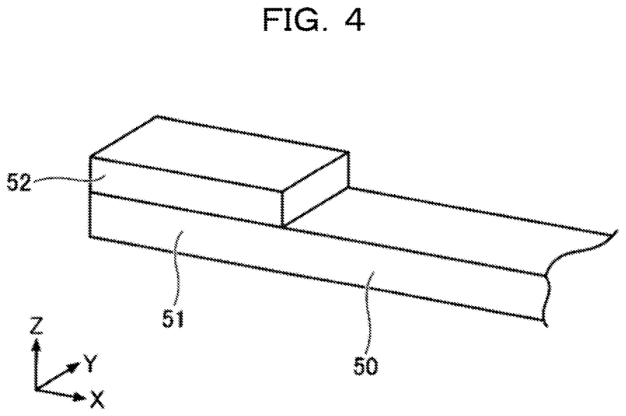

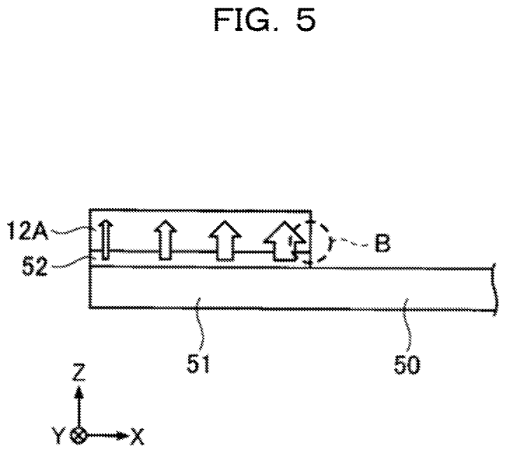

Here, a configuration of a bus bar 50 for comparison and current distribution will be described with reference to FIGS. 4 and 5. FIG. 4 is a diagram illustrating the bus bar 50 for comparison. FIG. 5 is a diagram for explaining current distribution in solder 52 connected to a terminal of the bus bar 50. Although a cross section is illustrated in FIG. 5, hatching is omitted. A terminal 51 of the bus bar 50 is not curved like the terminal 111 of the bus bar 110 according to the embodiment (refer to FIG. 3) and linearly extends in the X direction. A thickness of the solder 52 that connects between a flat upper surface of such a terminal 51 and the fiat lower surface of the pad 12A is uniform in the X direction.

When electronic power is supplied from the DC/DC converter 30 to the processor package 20 using such a bus bar 50 instead of the bus bar 110 illustrated in FIG. 1, currents are concentrated in a portion having the shortest distance between the DC/DC converter 30 and the processor package 20. Therefore, the currents are concentrated in a portion surrounded by a broken line circle B of the solder 52 in FIG. 5 (end portion of solder 52 on +X direction side). Because the thickness of the solder 52 is uniform in the X direction, a resistance of the bus bar 50 is minimized in a case where the current passes through the end portion of the solder 52 on the +X direction side.

Four arrows illustrated in the solder 52 indicate the current distribution. The thicker the arrow, the larger the amount of the current. The current distribution of the solder 52 is distribution in which more currents flow on the +X direction side, and fewer currents flow on the −X direction side. Therefore, electromigration occurs in the portion surrounded by the broken line circle B, and the solder 52 is gradually broken from the end portion of the sorer 52 on the +X direction side. Typically, when the current density exceeds 10⁴A/cm², the electromigration occurs in the solder. Therefore, in the configuration of the solder 52, the electromigration may occur from the end portion side on the +X direction side due to an increase in the current amount. Note that, here, the solder 52 connected to the pad 12A has been described. However, if a terminal having a similar shape to the terminal 51 is connected to the pad 12B via solder, electromigration may similarly occur in an end portion on the −X direction side that has a shortest distance.

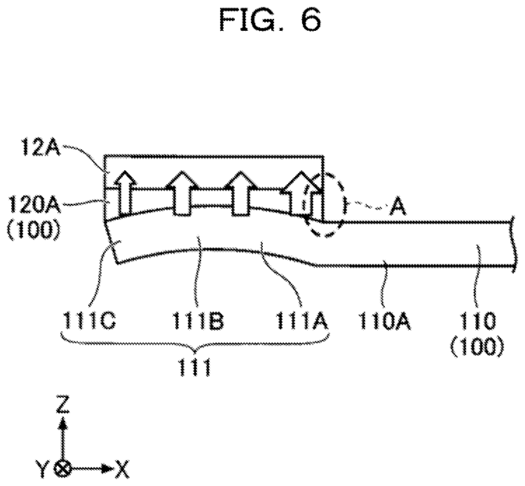

FIG. 6 is a diagram illustrating current distribution of the solder 120A. Although a cross section is illustrated in FIG. 6, hatching is omitted. In the terminal 111, the curved portion 111B that is positioned on the −X direction side is curved more upward than the end portion 111A on the +X direction side to which a current flows, and a portion of the solder 120A on the upper side of the curved portion 111B is thinner than the end portion of the solder 120A on the +X direction side indicated by a broken line circle A. Therefore, a resistance value of the solder 120A in the thickness direction of a portion above the curved portion 111B is smaller than that of the portion above the end portion 111A. As an example, the thickness of the portion above the curved portion 111B of the solder 120A is thinner than the thickness of the solder 52 for comparison, and the thickness of the portion above the end portion 111A is thicker than or equivalent to the thickness of the solder 52 for comparison.

In other words, for example, the portion above the curved portion 111B can obtain a current path having a smaller resistance value than the end portion of the solder 120A on the +X direction side (portion above end portion 111A) to be the shortest path. Therefore, a current density of the shortest path can be suppressed, and a current density of the curved portion 111B can be increased. As indicated by the four arrows in FIG. 6, a current density of the portion above the end portion 111A of the solder 120A and a current density of the portion above the curved portion 111B can be equalized. Note that the same applies to the terminal 112.

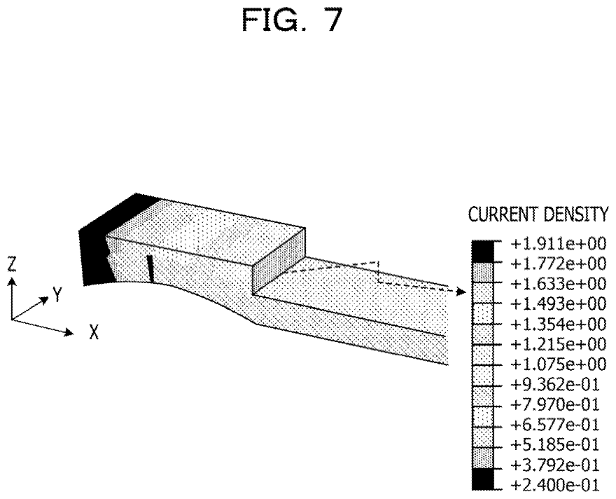

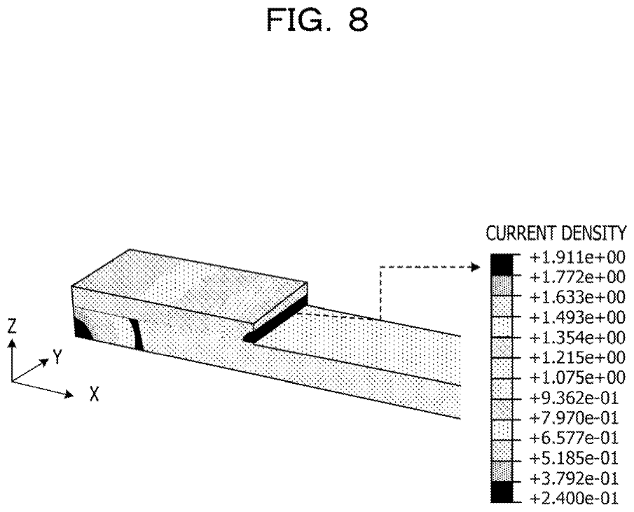

FIG. 7 is a diagram illustrating a simulation result of the current density of the solder 120A. FIG. 8 is a diagram illustrating a simulation result of a current density of the solder 52 connected on the terminal 51 of the bus bar 50 for comparison. When FIGS. 7 and 8 are compared, the current density of the end portion of the solder 52 on the +X direction side is very high in FIG. 8 and is about 1.91 (A/mm²). On the other hand, the current density of the end portion of the solder 120A on the +X direction side illustrated in FIG. 7 is reduced by about 26% to about 1.41 (A/mm²).

As described above, by using the bus bar 110 that includes the terminal 111 including the curved portion 111B, it is possible to reduce the current density of the end portion of the solder 120A on the +X direction side. This similarly applies to the terminal 112 that includes the curved portion 112B, and the current density of the end portion of the solder 120B on the −X direction side can be reduced. The end portion of the solder 120A on the +X direction side and the end portion of the solder 120B on the −X direction side are portions included in the shortest path of the current. In this way, by using the bus bar 110, the current density of the shortest path of the current can be lowered, the current distribution in the solder 120A and 120B is dispersed in the X direction, and it is possible for a damage caused by the electromigration to hardly occur. Furthermore, an occurrence time of the damage caused by the electromigration can be delayed.

Therefore, it is possible to provide the bus bar connection structure 100 that suppresses the increase in the current density. A life of metal due to the electromigration is expressed by the Black's equation and can be used as a value inversely proportional to the square of the current density. When the current density is reduced from about 1.91 (A/mm²) to about 1.41 (A/mm²), the life of the solder 120A is prolonged by about 80%.

Furthermore, the terminals 111 and 112 respectively include the curved portions 111B and 112B at the central portion in the X direction, and the front end portions 111C and 112C at the ends in the X direction are positioned on the lower side of the curved portions 111B and 112B. In other words, for example, the terminal 111 has a shape symmetrical in the X direction, and the terminal 112 has a shape symmetrical in the X direction. Because the terminals 111 and 112 are respectively connected to the pads 12A and 12B by the solder 120A and 120B, the end portion 111A and the front end portion 111C are positioned on both sides of the curved portion 111B, and the end portion 112A and the front end portion 112C are positioned on both sides of the curved portion 112B so that connection strengths (joining strength) of the terminals 111 and 112 by the solder 120A and 120B are equal to each other in the X direction.

On the substrate 10, the processor package 20 is mounted via the bump 21, and the DC/DC converter 30 is mounted. The bump 21 is formed of solder, and the DC/DC converter 30 and the via 11B are connected by solder or the like. Therefore, in a process for manufacturing the electronic device 1, there may be a case where the bus bar 110 is connected to the pads 12A and 12B by the solder 120A and 120B and the bus bar 110 is positioned on the lower side of the substrate 10 before the solder 120A and 120B is completely cured. In such a case, by forming the terminals 111 and 112 to have the shapes symmetrical in the X direction, misalignment of the bus bar 110 or the like can be suppressed, and it is possible to ensure reliability of a connection portion between the bus bar 110 and the pads 12A and 12B connected by the solder 120A and 120B.

Furthermore, because the curved portions 111B and 112B are continuously curved like an arc in the XZ cross-sectional view between the end portions 111A and 112A and the front end portions 111C and 112C, the thickness of the solder 120A and 120B continuously changes in the X direction, and the current distribution can be gently changed in the X direction. This also makes it possible to ensure the reliability of the connection portion connected by the solder 120A and 120B.

Note that, in the above, a form of the terminals 111 and 112 has been described of which the curved portions 111B and 112B at the center in the X direction of the terminals 111 and 112 are curved in an arc in the XZ cross-sectional direction. However, it is sufficient that the upper surfaces of the terminals 111 and 112 be curved so that the thickness of the end portion of the solder 120A on the +X direction side is thicker than other portions and the thickness of the end portion of the solder 120B on the −X direction side is thicker than the other portions. It is sufficient that the upper surfaces of the terminals 111 and 112 be curved so that the current densities of the end portion of the solder 120A on the +X direction side and the end portion of the solder 120B on the −X direction side can be more lowered than that in the current distribution of the solder 52 for comparison (refer to FIG. 4).

Furthermore, in the above, a form has been described in which the front end portions 111C and 112C are both ends of the terminals 111 and 112 of the bus bar 110. However, portions of the bus bar 110 existing in portions on the front side of the front end portions 111C and 112C may exist, and the front end portions 111C and 112C may be further extended. In this case, the portions indicated as the front end portions 111C and 112C are end portions on the opposite side of the end portions 111A and 112A in the X direction.

Furthermore, in the above, a form has been described in which the terminals 111 and 112 are bent by pressing or the like. Therefore, the lower surfaces of the terminals 111 and 112 are curved. However, convex portions that are projected like the curved portions 111B and 112B may be provided on the upper surface sides of the terminals 111 and 112. In this case, only the upper surfaces of the terminals 111 and 112 are curved to be projected upward, and the lower surfaces are flat.

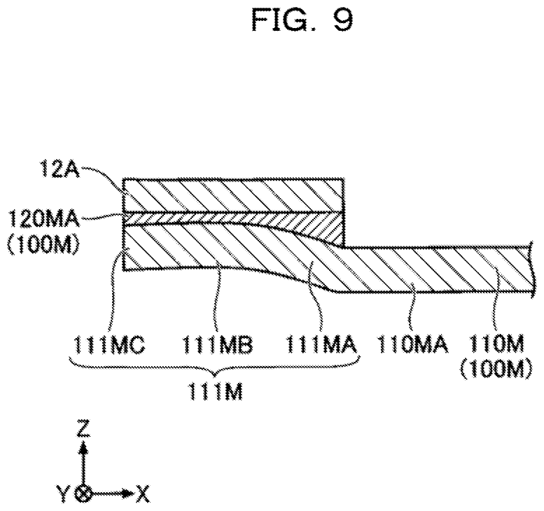

Furthermore, a configuration similar to a bus bar 110M illustrated in FIG. 9 may be used. FIG. 9 is a cross-sectional diagram illustrating the bus bar 110M according to a modification of the embodiment. The bus bar 110M includes a base 110MA and a terminal 111M. Here, a terminal on the +X direction side is omitted. However, as an example, it is sufficient that the terminal have a shape symmetrical with the terminal 111M in the X direction. The terminal 111M includes an end portion 111MA, a curved portion 111MB, and a front end portion 111MC, and the curved portion 111MB is curved upward and toward a pad 12A with respect to the end portion 111MA. The front end portion 111MC is not curved with respect to the curved portion 111MB, and a position of the front end portion 111MC is equal to a position of a portion of the curved portion 111B most projected in the +Z direction (end portion of curved portion 111B on −X direction side) in the Z direction.

When such a terminal 111M is connected to the pad 12A by a solder material, a thickness of a portion of solder 120MA above the end portion 111MA is thicker than a thickness of each of portions above the curved portion 111MB and the front end portion 111MC. Therefore, a current density of the end portion of the solder 120MA on the +X direction side can be reduced. In this way, by using the bus bar 110M, the current density of the shortest path of the current can be lowered, the current distribution in the solder 120MA is dispersed in the X direction, and it is possible for a damage caused by the electromigration to hardly occur. Furthermore, an occurrence time of the damage caused by the electromigration can be delayed.

Therefore, it is possible to provide a bus bar connection structure that suppresses an increase in the current density. Note that the shape of the terminal of the bus bar 110M on the +X direction side may be different from that of the terminal 111M.

Although the bus bar connection structure according to the exemplary embodiment has been described above, the embodiment is not limited to the embodiment disclosed in detail, and the various changes and alterations could be made hereto without departing from the scope of claims. Regarding the above embodiment, the following supplementary notes are further disclosed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
a bus bar that includes a first terminal and a second terminal and extends between the first terminal and the second terminal on a side of a first surface of a substrate;
first solder configured to pass through the substrate in a thickness direction and connect a first through terminal connected to a first electronic component that is disposed on a second surface side of the substrate and the first terminal; and
second solder configured to pass through the substrate in the thickness direction and connect a second through terminal connected to a second electronic component disposed on the second surface side of the substrate and the second terminal.

2. The electronic device according to claim 1, wherein
the first terminal includes a first approaching portion that is positioned on a side farther from the second terminal than a first end portion on the second terminal side in an extending direction of the bus bar and is positioned closer to the first through terminal than the first end portion,
the second terminal includes a second approaching portion that is positioned on a side farther from the first terminal than a second end portion on the first terminal side in the extending direction of the bus bar and is positioned closer to the second through terminal than the second end portion,
regarding a thickness of the first solder, a portion connected to the first end portion is thicker than a portion connected to the first approaching portion, and
regarding a thickness of the second solder, a portion connected to the second end portion is thicker than a portion connected to the second approaching portion.

3. The electronic device according to claim 2, wherein
the first terminal is bent so as to approach the first through terminal from the first end portion to the first approaching portion in the extending direction of the bus bar, and
the second terminal is bent so as to approach the second through terminal from the second end portion to the second approaching portion in the extending direction of the bus bar.

4. The electronic device according to claim 2, wherein
a first contact surface of the first terminal that has contact with the first solder is bent so as to approach the first through terminal from the first end portion to the first approaching portion in the extending direction of the bus bar, and
a second contact surface of the second terminal that has contact with the second solder is bent so as to approach the second through terminal from the second end portion to the second approaching portion in the extending direction of the bus bar.

5. The electronic device according to claim 2, wherein
the first approaching portion is provided at a central portion in the extending direction of the first terminal, and the first approaching portion is positioned closer to the first through terminal than the side farther from the second terminal than the first approaching portion of the first terminal, and
regarding the thickness of the first solder, a portion connected to the side farther from the second terminal than the first approaching portion is thicker than a portion connected to the first approaching portion.

6. The electronic device according to claim 5, wherein
the first terminal is bent toward the first through terminal from the first end portion to the first approaching portion in the extending direction of the bus bar and is bent so as to be separated from the first through terminal from the first approaching portion to the side farther from the second terminal than the first approaching portion.

7. The electronic device according to claim 5, wherein
a first contact surface of the first terminal that has contact with the first solder is bent toward the first through terminal from the first end portion to the first approaching portion in the extending direction of the bus bar and is bent so as to be separated from the first through terminal from the first approaching portion to the side farther from the second terminal than the first approaching portion.

8. The electronic device according to claim 5, wherein
the second approaching portion is provided at a central portion in the extending direction of the second terminal, and the second approaching portion is positioned closer to the second through terminal than the side farther from the first terminal than the second approaching portion of the second terminal, and
regarding the thickness of the second solder, a portion connected to the side farther from the first terminal than the second approaching portion is thicker than a portion connected to the second approaching portion.

9. The electronic device according to claim 7, wherein
the second terminal is bent toward the second through terminal from the second end portion to the second approaching portion in the extending direction of the bus bar and is bent so as to be separated from the second through terminal from the second approaching portion to the side farther from the first terminal than the second approaching portion.

10. The electronic device according to claim 8, wherein
a second contact surface of the second terminal that has contact with the second solder is bent toward the second through terminal from the second end portion to the second approaching portion in the extending direction of the bus bar and is bent so as to be separated from the second through terminal from the second approaching portion to the side farther from the first terminal than the second approaching portion.

11. An electronic device comprising:
a bus bar that includes a first terminal and a second terminal and extends between the first terminal and the second terminal on a first surface side of a substrate;
a first connection unit configured to pass through the substrate in a thickness direction and connect a first through terminal connected to a first electronic component that is disposed on a second surface side of the substrate and the first terminal; and
a second connection unit configured to pass through the substrate in the thickness direction and connect a second through terminal connected to a second electronic component that is disposed on the second surface side of the substrate and the second terminal, wherein
the first terminal includes a first approaching portion that is positioned on a side farther from the second terminal than a first end portion on the second terminal side in an extending direction of the bus bar and is positioned closer to the first through terminal than the first end portion,
the second terminal includes a second approaching portion that is positioned on a side farther from the first terminal than a second end portion on the first terminal side in the extending direction of the bus bar and is positioned closer to the second through terminal than the second end portion,
regarding a thickness of the first connection unit, a portion connected to the first end portion is thicker than a portion connected to the first approaching portion, and
regarding a thickness of the second connection unit, a portion connected to the second end portion is thicker than a portion connected to the second approaching portion.
